(19) United States
(12) Patent Application Publication
(10) Pub. No.: US 2020/0141794 A1
(43) Pub. Date: May 7, 2020

(54) VIBRATION SENSOR

(71) Applicant: YAMAHA CORPORATION, Hamamatsu-shi (JP)

(72) Inventors: Kunio HIYAMA, Hamamatsu-shi (JP); Yuki UEYA, Iwata-shi (JP); Ichiro FUTOHASHI, Hamamatsu-shi (JP); Katsunori SUZUKI, Hamamatsu-shi (JP)

(21) Appl. No.: 16/727,992

(22) Filed: Dec. 27, 2019

Related U.S. Application Data
(63) Continuation of application No. PCT/JP2018/017076, filed on Apr. 26, 2018.

(30) Foreign Application Priority Data
Jun. 30, 2017 (JP) 2017-128869
Mar. 6, 2018 (JP) 2018-039332

(51) Int. Cl. G01H 11/08; G01L 1/16

(52) U.S. Cl. CPC G01H 11/08; H01L 41/1132; G01L 1/167

(57) ABSTRACT

A vibration sensor in one aspect of the present invention includes a vibration detection element that has a sheet-shaped piezoelectric element and a pair of electrodes superposed on a front side and a rear side of the piezoelectric element, and a rear surface side gel layer superposed on a side where the vibration detection element faces a surface of a living body.

### BACKGROUND OF THE INVENTION

The present invention relates to a vibration sensor.

### DESCRIPTION OF RELATED ART

Measuring or observing vibrations originating in a living body, such as a heartbeat, pulse wave, blood-flow sound, and/or breathing sound (not limited to sound wave vibrations within the audible range but including low frequency vibrations and ultrasonic vibrations in the non-audible range) enables, for example, diagnosis, health management, and the like. These vibrations originating in the living body are collectively referred to as “biological vibrations.” With regard to the pulse wave of a human body, an apparatus for measuring a pulse waveform by irradiating an artery under the skin with a light beam and receiving the reflected light with a sensor has been in practical use. This method, however, has the following issues: the sensor is set unstably to the skin, and a high-precision optical sensor must be made available. These issues make it difficult to obtain a fine pulse waveform. In particular, the blood-flow sound includes not merely a heart rate, but also various information indicating the states of blood vessels and blood. Thus, the desired vibration sensor is adapted so that it directly adheres to the skin so as to directly detect the different biological vibrations.

In terms of apparatuses for detecting biological vibrations, for example, Japanese Unexamined Patent Application, Publication No. 2002-177227 sets forth a pulse wave detection apparatus in which a pressure-sensitive element is in press contact with a wrist to detect vibrations as pressure changes on the surface of a human body. The pulse wave detection apparatus described in the publication is comprised of a clip plate having a C-shaped cross section for holding a pressure-sensitive element (a piezoelectric member) on the surface of a wrist; an air bag disposed between the pressure-sensitive element and the clip plate for pressing the pressure-sensitive element against the wrist; a cloth band wound around the wrist with the pressure-sensitive element, the clip plate, and the air bag being kept in position; and a bent plate extending distally (out to a distal end) from the clip plate to restrict the movement of the wrist.

Although, in press contact with the wrist in the pulse wave detection apparatus described in the aforementioned publication, the cloth band is used to hold the pressure-sensitive element, the cloth band, because of its large dimensions, receives biological vibrations from sources different from those it is intended to detect and/or sound wave vibrations propagating externally in the air transmitted therethrough. As such vibrations are transmitted to it, the cloth band, even if not in direct contact with the pressure-sensitive element, presses the outside surface of the air bag pressurizing the pressure-sensitive element and alters the pressure inside the air bag, introducing noise to the pressure-sensitive element.

In addition, the pulse wave detection apparatus described in the aforementioned publication uses air pressure to press the pressure-sensitive element against the surface of a living body, and may cause a subject discomfort or occasional pain. Accordingly, long and continuous use of the apparatus is avoided. In addition, applying a pulse wave detection apparatus designed to press a pressure-sensitive element against a living body tends to result in pulse waveforms deviating from the normal pulse waves of the subject. These deviations occur due to the influence of the subject's stress originating from discomfort or pain and/or a physical influence resulting from strong pressure being applied to blood vessels.

### PRIOR ART DOCUMENTS

### Patent Documents

Patent Document 1: Japanese Unexamined Patent Application, Publication No. 2002-177227

### SUMMARY OF THE INVENTION

### Problems to be Solved by the Invention

In light of the aforementioned disadvantages, it is an object of the present invention to provide a vibration sensor that has a greater S/N (signal-to-noise) ratio and alleviates the discomfort of a subject.

### Means for Solving the Problems

A vibration sensor in one aspect of the present invention made to solve the aforementioned problems comprises a vibration detection element comprising a sheet-shaped piezoelectric member and a pair of electrodes superposed on the front side and the rear side of the piezoelectric member, and a rear surface side gel layer superposed on the side where the vibration detection element faces the surface of a living body.

### BRIEF DESCRIPTION OF THE DRAWINGS

FIG. 1 is a schematic sectional view of a vibration sensor in an embodiment according to the present invention;

FIG. 2 is a schematic sectional view of the vibration sensor in another embodiment different from the one in FIG. 1 according to the present invention;

FIG. 3 is a schematic sectional view of the vibration sensor in still another embodiment different from the ones in FIGS. 1 and 2 according to the present invention;

FIG. 4 is a schematic plan view of the vibration sensor in FIG. 3;

FIG. 5 is a schematic sectional view of the vibration sensor in an embodiment different from the ones in FIGS. 1 to 3 according to the present invention;

FIG. 6 is a schematic plan view of the vibration sensor in FIG. 5;

FIG. 7 is a schematic plan view of a gel casing used in a method for manufacturing the vibration sensor in FIG. 5;

FIG. 8 is a sectional view of the gel casing in FIG. 7 taken along the line A-A.

FIG. 9 is a schematic sectional view of the gel casing filled with an acoustic matching agent, in the method for manufacturing the vibration sensor where the gel casing in FIG. 7 is used;

FIG. 10 is a schematic sectional view of the gel casing with a vibration detection element inserted therein, in the method for manufacturing the vibration sensor where the gel casing in FIG. 7 is used;

FIG. 11 is a schematic sectional view of the vibration sensor in an embodiment different from the ones in FIGS. 1 to 3 and FIG. 5;

FIG. 12 is a schematic plan view of the vibration sensor in FIG. 11;

FIG. 13 is a schematic sectional view of the vibration sensor in an embodiment for reference; and

FIG. 14 is a schematic sectional view of the vibration sensor in an embodiment different from the ones in FIGS. 1 to 3, FIG. 5, and FIG. 11.

### DESCRIPTION OF EMBODIMENTS

Hereinafter, with reference to an appropriate drawing or drawings, embodiments of the present invention will be described in detail.

A vibration sensor in one aspect of the present invention made to solve the aforementioned problems comprises a vibration detection element comprising a sheet-shaped piezoelectric member and a pair of electrodes superposed on the front side and the rear side of the piezoelectric member, and a rear surface side gel layer superposed on the side where the vibration detection element faces the surface of a living body.

The vibration sensor may further comprise a front surface side gel layer superposed over the side of the vibration detection element, which is opposite the surface of the living body.

The front surface side gel layer extends beyond the vibration detection element in planar view.

The rear surface side gel layer and the front surface side gel layer may be shaped integrally.

The vibration sensor may comprise a covering portion that covers a front surface side of the front surface side gel layer and is capable of pushing the front surface side gel layer down from the front surface side, and a cap comprising a connection portion for connecting the covering portion to the surface of the living body.

In the vibration sensor, an average thickness of the rear surface side gel layer is preferably no less than 0.2 mm and no greater than 3.0 mm.

In the vibration sensor, an elastic modulus of the rear surface side gel layer is preferably no greater than 1 MPa.

In the vibration sensor, the substances that constitute the rear surface side gel layer preferably comprise hydrogel.

In the vibration sensor, the rear surface side gel layer may be electrically conductive and be electrically connected to one of the pair of electrodes.

Since the vibration sensor in this aspect of the present invention has the rear surface side gel layer superposed on the side where the vibration detection element faces the surface of the living body, the rear surface side gel layer is in close contact with the surface of the living body to hold the vibration detection element over the body's surface and allow the internal vital sounds to be efficiently transmitted to the vibration detection element. Thus, the vibration sensor can efficiently convert biological vibrations into electrical signals. The vibration sensor, the rear surface side gel layer of which is able to adhere to the surface of the living body, can have a total projection area almost the same as that of the vibration detection element. This results in noise being less transmissible to the vibration sensor, which brings about a greater S/N ratio.

Since the vibration sensor adheres to the surface of the living body due to its rear surface side gel layer without exerting pressure on the living body, it can detect biological vibrations in a natural waveform. Moreover, as the rear surface side gel layer has more durable stickiness even after it is removed from and re-applied to the surface of the living body, temporary removal for positional adjustment or repetitive use of the vibration sensor does not easily deteriorate its detection accuracy. Furthermore, the vibration sensor, being adapted so that its dimensions are relatively reduced, alleviates the feeling of discomfort given to a subject. Thus, the vibration sensor permits measurement of biological vibrations over a long time.

### First Embodiment

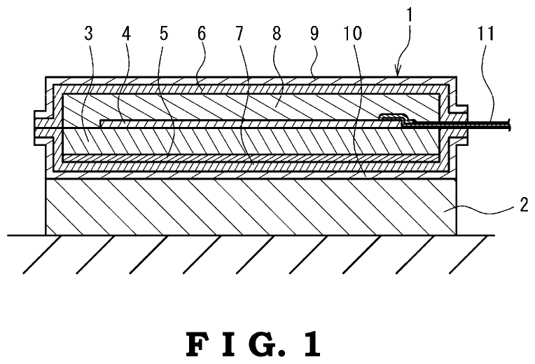

FIG. 1 shows a vibration sensor in an embodiment according to the present invention. The vibration sensor is disposed in close contact with the surface of a living body such as a human being or an animal and is used to detect vibrations in the living body.

The vibration sensor has a sheet-shaped vibration detection element 1 and a rear surface side gel layer 2 superposed on the face where the vibration detection element 1 faces the surface of the living body. In the present invention, the surface facing the surface of the living body is expressed as “rear surface,” while the obverse surface is expressed as “front surface.”

### Vibration Detection Element

The vibration detection element 1 has a sheet-shaped piezoelectric member 3 and a pair of electrodes 4 and 5 superposed on the front side and the rear side of the piezoelectric member 3. Also, the vibration detection element 1 has a pair of shield layers 6 and 7 covering the pair of electrodes 4 and 5 on their respective surfaces opposite the piezoelectric member 3, an isolator layer 8 disposed between the electrode 4 and the shield layer 6 on the side opposite the surface of the living body (front side) and having an elastic modulus approximate to that of the piezoelectric member 3, a pair of protective layers 9 and 10 covering the shield layers 6 and 7 on their respective surfaces opposite the piezoelectric member 3, and a lead 11 having one end connected to the front side electrode 4 and the other end externally extended. It should be noted that “having an elastic modulus approximate to that of the piezoelectric member” means that the difference in elastic modulus from the piezoelectric member is no greater than 50%, preferably no greater than 30% of the elastic modulus of the piezoelectric member.

### Piezoelectric Member

The piezoelectric member 3 is formed of a piezoelectric material that converts pressure into voltage, and, when it is given stress by way of a pressure wave from a biological vibration, a potential difference arises between the front side and the rear side depending on the change in stress.

The piezoelectric material the piezoelectric member 3 is composed of may be an inorganic material such as lead zirconate titanate, but is preferably a high-polymer piezoelectric material that is sufficiently flexible to permit close contact with the surface of a living body.

Examples of the high-polymer piezoelectric material include polyvinylidene fluoride (PVDF), vinylidene fluoride-trifluoroethylene copolymer (P(VDF/TrFE)), vinylidene cyanide-vinyl acetate copolymer (P(VDCN/VAc)), and the like.

Alternatively, the piezoelectric member 3 may be made of a non-piezoelectric material, such as polytetrafluoroethylene (PTFE), polypropylene (PP), polyethylene (PE), polyethylene terephthalate (PET), or the like, that is processed to have numerous flat pores and has further undergone polarization and then electrification of the surfaces opposite the flat pores by means of a corona discharge, for example, to acquire the piezoelectric property.

For the lower limit of the average thickness of the piezoelectric material 3, 10 μm is preferred and 50 μm is more preferred. On the other hand, the upper limit of the average thickness of the piezoelectric member 3 is preferably 500 μm, and more preferably 200 μm. If the average thickness of the piezoelectric member 3 is less than the above-defined lower limit, the strength of the piezoelectric member 3 may be insufficient. Conversely, if the average thickness of the piezoelectric member 3 exceeds the above-defined upper limit, the deformability of the piezoelectric member 3 is reduced, which may lead to insufficient detection sensitivity.

The piezoelectric member 3 can be dimensioned to match the region where a biological vibration to be detected originates. For instance, on the assumption that a pulse wave is to be detected by the vibration sensor, the piezoelectric member 3 can be shaped into a square or a rectangle with a width of no less than 1 cm and no greater than 5 cm, and a length of no less than 1 cm and no greater than 10 cm.

The piezoelectric member 3 is preferably oriented so as to generate a positive charge on the front surface side and a negative charge on the read surface side. This makes it possible to detect the potential on the front surface side of the piezoelectric member 3 through use of the potential on the rear surface side of the piezoelectric member 3 as a reference potential (ground), thereby enabling stable detection.

### Electrodes

The electrodes 4 and 5 are superposed on both surfaces of the piezoelectric member 3 and are used to detect the potential difference between the front side and the rear side surfaces of the piezoelectric member 3. For that purpose, the electrodes 4 and 5 are connected to a detection circuit (not illustrated).

For the purpose of the stable detection of biological vibrations, it is preferable that the electrode 4 or 5 is grounded. Further, it is preferable that the above-mentioned electrode to be grounded is disposed on the side of the piezoelectric member 3 that generates a negative charge. The ground to which the electrode 4 or 5 is connected may be a human body in order to simplify wiring.

The electrodes 4 and 5 may be made of any material that is electrically conductive, and examples of the material include metals like aluminum, copper, and nickel, and carbon or the like.

The method of superposing the electrodes 4 and 5 over the piezoelectric member 3 is not particularly limited, and may comprise, for example, metal vapor deposition, printing in carbon conductive ink, silver paste coating and drying, or the like.

The average thickness of the electrodes 4 and 5 is not particularly limited, and may be, for example, no less than 0.1 μm and no greater than 30 μm depending on the superposing method. If the average thickness of the electrodes 4 and 5 is less than the above-defined lower limit, the strength of the electrodes 4 and 5 may be insufficient. Conversely, if the average thickness of the electrodes 4 and 5 exceeds the above-defined upper limit, the transmission of vibration to the piezoelectric member 3 may be hindered.

The electrodes 4 and 5 may be formed by being divided into a plurality of regions in planar view, and may effectively cause the vibration detection element 1 to function as if it were a plurality of piezoelectric elements.

It is preferable that the front surface side electrode 4 serving as the positive electrode is slightly smaller than the rear surface side electrode 5 serving as the negative electrode and that the piezoelectric member 3 and the isolator layer 8 are in contact with each other around the periphery of the front surface side electrode 4. This facilitates electrical insulation between the front surface side electrode 4 and the shield layer 6.

### Shield Layer

The shield layers 6 and 7 are made of an electrically conductive material, and they shield electromagnetic waves and prevent noise voltage from being applied to the electrodes 4 and 5.

The shield layers 6 and 7 of this embodiment are electrically joined to each other outside the piezoelectric member 3, the rear surface side electrode 5, and the isolator layer 8 in planar view.

The shield layers 6 and 7 are preferably connected to ground to ensure electromagnetic shielding. Thus, the shield layers 6 and 7 may be electrically connected to the rear surface side electrode 5.

For the shield layers 6 and 7, metal foil, layers of vaporized and deposited metal, layers of plated metal, layers of electrically conductive ink coating, or the like can be used, and above all, the metal foil is preferable.

Examples of the materials for the shield layers 6 and 7 include copper and aluminum or the like, which may be plated with gold, nickel, silver, or the like to prevent reactions such as oxidation.

Also preferable in order to simplify the fabrication of the vibration detection element 1 is using a laminated body of the shield layers 6 and 7 and the below-mentioned protective layers 9 and 10. For the laminated body, for example, a vapor-deposited film or a laminate film can be used, and a laminated body commercially available as a shield film, for example, a laminate body including other layers such as an insulating layer that insulates from the electrode 4, may be used. The shield layers 6 and 7 may be those commercially available as a shield film and include, for example, a layered member including another layer such as an insulation layer that insulates from the electrode 4.

The shield layers 6 and 7 may be bonded to the rear surface side electrode 5 and the isolator layer 8 with an adhesive.

The average thickness of the shield layers 6 and 7 may be, for example, no less than 0.5 μm and no greater than 20 μm, depending on the formation method. If the average thickness of the shield layers 6 and 7 is less than the above-defined lower limit, sufficient electromagnetic shielding effect may not be obtained. Conversely, if the average thickness of the shield layers 6 and 7 exceeds the above-defined upper limit, the vibration detection element 1 may be insufficiently flexible, or the transmission of vibration to the piezoelectric member 3 may be hindered, possibly deteriorating the detection sensitivity of the vibration sensor.

### Isolator Layer

The isolator layer 8 is provided to secure distance between the front side electrode 4 and the front side shield layer 6 and to reduce the parasitic capacitance formed between the electrode 5 and the shield layer 6.

The isolator layer 8 is electrically non-conductive and is made of a material having an elastic modulus approximate to that of the piezoelectric member 3. The average thickness of the isolator layer 8 is preferably almost the same as that of the piezoelectric member 3 so as not to hinder the piezoelectric member 3's deformation in response to sound wave vibrations.

Specifically, for the isolator layer 8, the same material as that of the piezoelectric member 3 can be used. In particular, in the case where the piezoelectric member 3 has undergone polarization and then electrification of the surfaces opposite the flat pores in its material by means of a corona discharge or the like, the same material as the one used for the pre-polarized piezoelectric member 3 is suitable for the isolator layer 8.

### Protective Layer

The protective layers 9 and 10 are provided to prevent the shield layers 6 and 7 from being damaged. The protective layers 9 and 10 can be made of pliable resin.

Although the resins of which the protective layers 9 and 10 may be composed are not particularly limited and examples of the resins include polyolefin, polyurethane, and the like, the polyurethane, which excels in pliability, is especially suitable for use among these examples.

The average thickness of the protective layers 9 and 10 may be, for example, no less than 10 μm and no greater than 50 μm. If the average thickness of the protective layers 9 and 10 is less than the above-defined lower limit, the protective layers 9 and 10 may be broken. Conversely, if the average thickness of the protective layers 9 and 10 exceeds the above-defined upper limit, the transmission of biological vibrations to the piezoelectric member 3 may be hindered.

### Lead

The lead 11 is a covered electric wire connected to the front surface side electrode 4 and is provided to enable an external circuit not illustrated to measure the potential on the electrode 4. The lead 11, if a multi-core cable is used for it, can also be used as the wiring to connect the rear surface side electrode 5 and the shield layer 6 to ground.

For the lead 11, for example, vinyl-insulated wire, enameled wire, and the like can be used.

The lead 11 can be connected to the front surface side electrode 4 (the rear surface side electrode 5 or the shield layer 6 as required) by using, for example, conductive adhesive, solder, or the like.

### Rear Surface Side Gel Layer

The rear surface side gel layer 2 is composed of high-polymer gel, the stickiness of which enables the vibration detection element 1 to cling to the surface of a living body and the biological vibration of the living body to propagate to the vibration detection element. The rear surface side gel layer 2 in this embodiment is superposed over almost all of the rear surface of the vibration detection element 1.

The material of the rear surface side gel layer 2 is preferably that which approximates the vibration properties of the living body and behaves, when stuck onto the surface of the living body, as if it were the thickened skin of the living body. Specifically, the rear surface side gel layer 2 preferably has an elastic modulus of no greater than 1 MPa.

Moreover, the material of the rear surface side gel layer 2 is selected so as to be unlikely to cause skin irritation or any other dermal symptoms if it is directly applied to the skin. For a gel having such safety, a hydrogel containing the dispersion medium of water is preferable, or alternatively, an organogel containing the dispersion medium of organic solvent may be used. Examples of safe hydrogels include hydrophilic polyurethane gel, crosslinked poly (acrylic acid) gel, and so forth; and particularly preferably used is the hydrophilic polyurethane gel.

A lower limit of the average thickness of the rear surface side gel layer 2 is preferably 0.2 mm, and more preferably 0.5 mm. On the other hand, an upper limit of the average thickness of the rear surface side gel layer 2 is preferably 3.0 mm, and more preferably 2.0 mm. If the average thickness of the rear surface side gel layer 2 is less than the lower limit, its stickiness may be insufficient due to the moisture volatizing or the like, which may cause the vibration sensor to fail to securely adhere to the surface of the living body. Conversely, if the average thickness of the rear surface side gel layer 2 exceeds the upper limit, the transmission efficiency of biological vibrations may be unnecessarily lowered.

When the material of the rear surface side gel layer 2 is hydrogel, the moisture content may be, for example, no less than 70% by mass and no greater than 90% by mass, although this depends on the type of gel base material (high polymer). If the moisture content of the rear surface side gel layer 2 is less than the above-defined lower limit, the transmission efficiency of biological vibrations may be lowered. Conversely, if the moisture content of the rear surface side gel layer 2 exceeds the above-defined upper limit, water may ooze out, causing it to easily slip on the surface of the living body.

### Advantages

Since the vibration sensor has the rear surface side gel layer 2 superposed on the side where the vibration detection element 1 faces the surface of the living body, the rear surface side gel layer 2 in close contact with the surface of the living body fastens the vibration detection element 1 to the surface of the living body and efficiently transmits the internal vital sounds to the vibration detection element 1. Thus, the vibration sensor can efficiently convert biological vibrations into electrical signals.

Further, the vibration sensor, the rear surface side gel layer 2 of which is able to adhere to the surface of the living body, can have a total projection area roughly equal to that of the vibration detection element 1 and can have its dimensions relatively reduced. This results in less transmission of noise, such as biological vibrations from sources other than those intended for detection and/or sound wave vibrations propagating externally in the air, to the vibration sensor, which brings about a relatively increased S/N ratio.

Moreover, the vibration sensor adhere to the surface of the living body by means of the rear surface side gel layer 2, and thereby enables measurement of biological vibrations without exerting pressure on the living body. Hence, the vibration sensor can detect biological vibrations in a natural waveform.

Moreover, since the vibration sensor adheres to the surface of the living body by means of the rear surface side gel layer 2, it has more durable stickiness, even after it is removed from and re-applied to the surface of the living body. Hence, temporary removal for positional adjustment or repetitive use of a vibration sensor that has already been used does not easily deteriorate its detection accuracy.

Furthermore, the vibration sensor, being adapted so that it adheres to the surface of the living body by means of the rear surface side gel layer 2 being superposed on the rear surface of the vibration detection element 1, can have its dimensions relatively reduced. Hence, the feeling of discomfort given to a subject is minor, meaning that the burden put on the subject in the case of measuring biological vibrations over an extended period of time is minimal.

Moreover, the vibration sensor, the vibration detection element 1 of which possesses the shield layers 6 and 7, can block electromagnetic noise via the shield layer 6, which brings about an enhanced S/N ratio.

Further, the vibration sensor, the vibration detection element 1 of which possesses the isolator layer 8 between the front surface side electrode 4 and the shield layer 6, can reduce the parasitic capacitance formed between the electrode 4 and the shield layer 6 via the isolator layer 8. Also, as the isolator layer 8 has an elastic modulus approximate to that of the piezoelectric member 3, deformation of the piezoelectric member 3 is less likely to be hindered; this, in turn, minimizes the reduction in biological vibration detection efficiency. Thus, the isolator layer 8 enables the vibration sensor to attain a more greatly enhanced S/N ratio.

Additionally, the vibration sensor, the vibration detection element 1 of which further possesses the protective layers 9 and 10 covering the shield layers 6 and 7, can avoid a reduction in the S/N ratio resulting from damage to the shield layers 6 and 7. Also, as the vibration sensor is adapted such that the protective layers 9 and 10 safeguard the shield layers 6 and 7, the handling of the vibration detection element 1 during fabrication is simplified, enabling provision at a relatively low price.

Furthermore, the vibration sensor, the protective layer 10 of which is laid between the rear surface side shield layer 7 and the rear surface side gel layer 2, permits the rear surface side gel layer 2 to be peeled from the vibration detection element 1 relatively easily without damaging the shield layer 7. Thus, the vibration sensor can have a used front surface side gel layer 2 peeled off to superpose a new front surface side gel layer 2, and in this way, it can be reused relatively easily.

### Second Embodiment

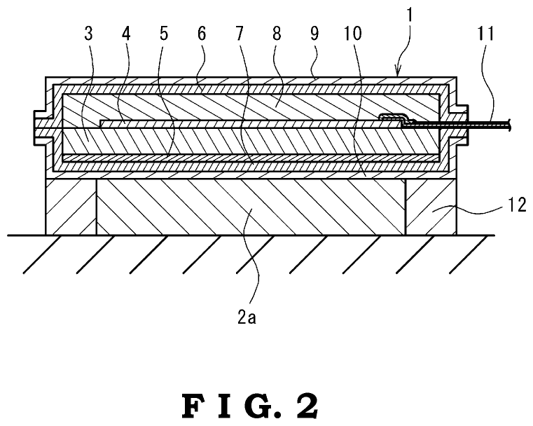

FIG. 2 shows the vibration sensor in another embodiment of the present invention. The vibration sensor in FIG. 2 is, similar to the one in FIG. 1, disposed in close contact with the surface of a living body such as a human being or an animal, and is used to detect vibrations of the living body.

The vibration sensor has a sheet-shaped vibration detection element 1, a rear surface side gel layer 2a superposed on areas of the rear surface of the vibration detection element 1 excepting the periphery of the same, and a frame member 12 disposed on the periphery of the rear surface of the vibration detection element 1 so as to surround the rear surface side gel layer 2a.

### Vibration Detection Element

The configuration of the vibration detection element 1 of the vibration sensor in FIG. 2 can be the same as that of the vibration detection element 1 of the vibration sensor in FIG. 1. Thus, for the vibration sensor in FIG. 2, identical reference symbols denote components identical to those of the vibration sensor in FIG. 1, and redundant explanations have been omitted.

### Rear Surface Side Gel Layer

The configuration of the rear surface side gel layer 2a of the vibration sensor in FIG. 2 is the same as that of the rear surface side gel layer 2 of the vibration sensor in FIG. 1 except that the rear surface side gel layer 2a is superposed only on the center region of the rear surface of the vibration detection element 1; that is, its planar dimensions are smaller.

The rear surface side gel layer 2a is preferably superposed on a region that faces the smaller of electrodes 4 and 5. Thus, the transmission of biological vibrations to the effective area of the vibration detection element 1 (i.e., an area over which the change in thickness of a piezoelectric member 3 can be detected) is not limited.

### Frame Member

The frame member 12 prevents the periphery of the vibration detection element 1 from adhering to the surface of the living body. This enables an operator to hook his or her fingernail onto the back of the vibration sensor from the periphery when peeling it from the surface of the living body after use, thereby facilitating removal of the sensor.

The frame member 12 is arranged on the periphery of the rear surface of the vibration detection element 1 of the vibration sensor, and the vibration sensor is used with the frame member 12 in close contact with the surface of the living body. This prevents a situation in which some other object is inserted between the vibration detection element 1 and the surface of the living body during use and the vibration sensor detaches from the surface of the living body.

Thus, it is preferable that the thickness of the frame member 12 is almost the same as that of the rear surface side gel layer 2a.

For the material of the frame member 12, an elastic resin is preferable, and a foamed resin may be used.

### Third Embodiment

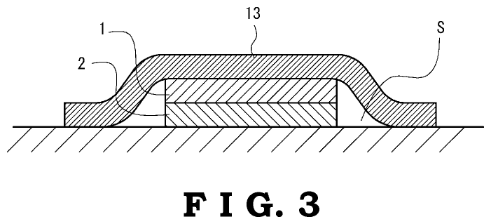

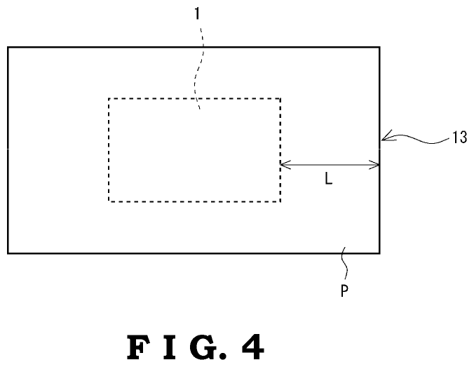

FIGS. 3 and 4 show the vibration sensor in another embodiment of the present invention. The vibration sensor in FIGS. 3 and 4 is, similar to the vibration sensor in FIG. 1, disposed in close contact with the surface of a living body such as a human being or an animal, for example, and is used to detect vibrations in the living body.

The vibration sensor has a sheet-shaped vibration detection element 1, a rear surface side gel layer 2 superposed on the side where the vibration detection element 1 faces the surface of the living body, and a front surface side gel layer 13 superposed on the side of the vibration detection element 1, which is opposite the surface of the living body.

The configuration of the vibration detection element 1 of the vibration sensor can be the same as that of the vibration detection element 1 of the vibration sensor in FIG. 1. Also, the configuration of the rear surface side gel layer 2 of the vibration sensor can be the same as that of the rear surface side gel layer 2 of the vibration sensor in FIG. 1. Hence, the vibration detection element 1 and the rear surface side gel layer 2 of the vibration sensor are denoted by the same reference numerals as those for the vibration sensor in FIG. 1, and explanations of the same have been omitted.

### Front Surface Side Gel Layer

The front surface side gel layer 13 is superposed over the front surface side of the vibration detection element 1 so as to cover a region in which the front surface side gel layer 13 overlaps the rear surface side gel layer 2 via the vibration element 1. As such, in this embodiment, the front surface side gel layer 13 is directly superposed atop the front surface of the vibration detection element 1.

The front surface side gel layer 13 extends beyond the vibration detection element 1 in planar view. The front surface side gel layer 13 is arranged so that its region extending beyond the peripheral edge of the vibration detection element 1 in planar view (hereinafter, also referred to as “overhanging region P”) is configured to adhere to the surface of the living body. The front surface side gel layer 13, as shown in FIG. 4, extends beyond the entire circumferential edge of the vibration detection element 1 (more specifically, from the entire circumferential edge of the vibration detection element 1 except the lead). In this way, the front surface side gel layer 13 is configured so that it can externally cover the entire surface region of the peripheral surfaces of the vibration detection element 1.

A lower limit of the average overhanging length L of the front surface side gel layer 13 from the peripheral edge of the vibration detection element 1 is preferably 3 mm, and more preferably 4 mm. On the other hand, an upper limit of the average overhanging length L is preferably 20 mm, and more preferably 10 mm. If the average overhanging length is less than the lower limit, the overhanging region P may not easily adhere to the surface of the living body. Conversely, if the average overhanging length exceeds the upper limit, the overhanging region P becomes unnecessarily large, and vibrations other than biological vibrations may be transmitted to the vibration detection element 1 via the overhanging region P.

The front surface side gel layer 13 and the rear surface side gel layer 2 are formed of separate sheet members. Also, the front surface side gel layer 13 is disposed at some distance from the rear surface side gel layer 2. In this way, as illustrated in FIG. 3, spaces S are provided between the front surface side gel layer 13 and the end faces of the vibration detection element 1 and the rear surface side gel layer 2.

The front surface side gel layer 13 is made of high polymer gel. The material of the front surface side gel layer 13 can be the same as the material of the rear surface side gel layer 2. The average thickness and moisture content of the front surface side gel layer 13 can be the same as those of the rear surface side gel layer 2.

The front surface side gel layer 13 functions as an anchor layer for the vibration sensor to reliably detect biological vibrations such as pulse waves. More specifically, the front surface side gel layer 13, being superposed on the front surface side of the vibration detection element 1 and adapted so that its overhanging region P adheres to the surface of the living body, achieves a pseudo-state of the vibration detection element 1 being embedded internally. In this way, the front surface side gel layer 13 inhibits the vibration detection element 1 from detecting any movement of the living body other than the vibrations in the living body. Thus, in the vibration sensor, the elastic modulus of the front surface side gel layer 13 may be greater than that of the rear surface side gel layer 2 so as to give more secure backing to the vibration detection element 1 from the outside thereof.

The vibration sensor, having its front surface side gel layer 13 superposed on the front surface side of the vibration detection element 1, can prevent uneven pressure from being applied to the front side and the rear side of the vibration detection element 1, and can more reliably detect biological vibrations.

In particular, the vibration sensor, having the front surface side gel layer 13 extending beyond the vibration detection element 1 in planar view and being adapted so that the overhanging region P adheres to the surface of the living body, can inhibit a part of the front surface side gel layer 13 superposed on the front surface side of the vibration detection element 1 from inadvertently working as a weight. This inhibition brings about more reliable detection of biological vibrations. Moreover, since the front surface side gel layer 13 is more likely to attenuate vibrations in the planar direction through the sheet, the vibration sensor aids in preventing non-biological vibrations introduced by overhanging region P from being transmitted to the vibration detection element 1.

The vibration sensor, having its front surface side gel layer 13 disposed at some distance from the rear surface side gel layer 2 and providing the spaces S between the front surface side gel layer 13 and the end faces of the vibration detection element 1 and the rear surface side gel layer 2, can keep external pressure exerted on a region in the vicinity of the peripheral edge of the piezoelectric member 3 while the overhanging region P adheres to the surface of the living body. This prevents the piezoelectric member 3 from being unintentionally deformed and enables the vibration sensor to easily and reliably detect biological vibrations.

### Fourth Embodiment

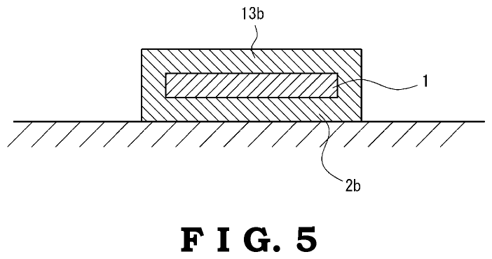

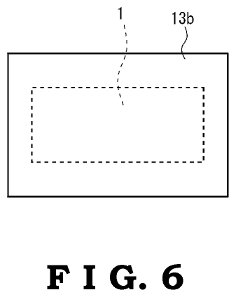

FIGS. 5 and 6 illustrate the vibration sensor in another embodiment of the present invention. The vibration sensor in FIGS. 5 and 6, similar to the vibration sensor in FIG. 1, is disposed in close contact with the surface of a living body such as a human being or an animal, and it is used to detect the vibrations in the living body.

The vibration sensor includes a sheet-shaped vibration detection element 1, a rear surface side gel layer 2b superposed on the side where the vibration detection element 1 faces the surface of the living body, and a front surface side gel layer 13b superposed on the side of the vibration detection element 1, which is opposite the surface of the living body.

The configuration of the vibration detection element 1 of the vibration sensor can be the same as that of the vibration detection element 1 of the vibration sensor in FIG. 1. Hence, the vibration detection element 1 of the vibration sensor is denoted by the same reference symbol as that for the vibration sensor in FIG. 1, and the explanation of the same has been omitted.

### Gel Layer

The rear surface side gel layer 2b is superposed on almost the entire rear surface side of the vibration detection element 1. The rear surface side gel layer 2b is directly superposed on the rear surface of the vibration detection element 1. Also, the front surface side gel layer 13b is superposed on almost the entire front surface side of the vibration detection element 1. The front surface side gel layer 13b is directly superposed on the front surface of the vibration detection element 1. The material of the rear surface side gel layer 2b and the front surface side gel layer 13b can be the same as that of the rear surface side gel layer 2 of the vibration sensor in FIG. 1. Moreover, the average thickness and moisture content of the rear surface side gel layer 2b and the front surface side gel layer 13b can be the same as those of the rear surface side gel layer 2 of the vibration sensor in FIG. 1.

The rear surface side gel layer 2b and the front surface side gel layer 13b are shaped integrally. In other words, the rear surface side gel layer 2b and the front surface side gel layer 13b are continuously made of the same material. The rear surface side gel layer 2b and the front surface side gel layer 13b cover the external surface of the vibration detection element 1 except the lead. The rear surface side gel layer 2b and the front surface side gel layer 13b are shaped, as a whole, in a flat form or, in the present embodiment, as a rectangular parallelepiped, having a hollow space inside, and the vibration detection element 1 is inserted into the hollow space.

The rear surface side gel layer 2b and the front surface side gel layer 13b have their respective planar extents shaped the same, and are in face-to-face arrangement with each other, having the vibration detection element 1 interposed therebetween, so as to join together outside the vibration detection element 1.

Moreover, the rear surface side gel layer 2b and the front surface side gel layer 13b may be integrated using a gel casing that has roughly rectangular outside and inside walls in face-to-face positions and three end walls connecting the side edges of the outside and inside walls to one another so as to provide an internal space to contain the vibration detection element 1. That is, the rear surface side gel layer 2b and the front surface side gel layer 13b may respectively include the inside wall and the outside wall of the gel casing and be joined together by the end walls.

The internal surfaces defining the internal space of the rear surface side gel layer 2b and the front surface side gel layer 13b may be in close contact with the external surface of the vibration detection element 1, and an opening between these internal surfaces and the external surface of the vibration detection element 1 may be filled with an acoustic matching agent such as a gel capable of suppressing the reflection of acoustic waves.

Since the vibration sensor's rear surface side gel layer 2b and front surface side gel layer 13b are shaped integrally, the rear surface side gel layer 2b and/or the front surface side gel layer 13b can be prevented from peeling from the vibration detection element 1. Also, although the rear surface side gel layer 2b and the front surface side gel layer 13b are not bonded to the vibration detection element 1, the vibration sensor can keep the rear surface side gel layer 2b and the front surface side gel layer 13b laminated to the vibration detection element 1. Furthermore, in the vibration sensor, because the rear surface side gel layer 2b and the front surface side gel layer 13b are joined to each other outside the end faces of the vibration detection element 1 so as to surround the vibration detection element 1, the rear surface side gel layer 2b and the front surface side gel layer 13b can provide external support to the end faces of the vibration detection element 1. In this way, the vibration sensor achieves a pseudo-state of the vibration detection element 1 being embedded internally, and it can inhibit the vibration detection element 1 from detecting movements of the living body other than vibrations in the living body. In addition, the vibration sensor can cause the rear surface side gel layer 2b and the front surface side gel layer 13b to exert pressure isotropically on the vibration detection element 1 when the rear surface side gel layer 2b and the front surface side gel layer 13b are in close contact with the external surface of the vibration detection element 1, which makes it easy to enhance the detection sensitivity.

### Manufacturing Method

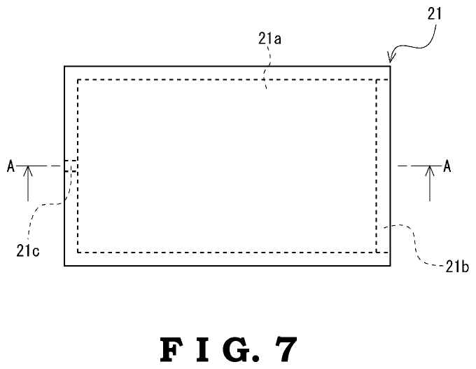

With reference to FIGS. 7 to 10, an example of a method for manufacturing the vibration sensor illustrated in FIGS. 5 and 6 will be described. This method includes a step of preparing a casing 21 made of gel (a gel casing preparation step), a step of filling the gel casing 21 prepared in the gel casing preparation step with an acoustic matching agent 22 (an acoustic matching agent filling step), and a step of inserting the vibration detection element 1 into the gel casing 21 after the acoustic matching agent filling step (a vibration detection element insertion step).

### Gel Casing Preparation Step

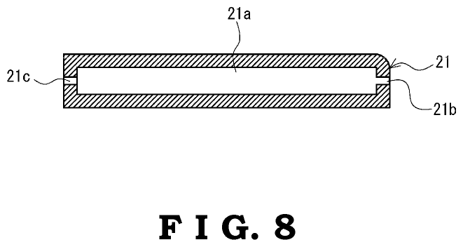

The gel casing preparation step, as illustrated in FIGS. 7 and 8, involves preparing the casing 21 made of gel where an almost rectangular parallelepiped plate-shaped body (or strip-shaped body) has one of its end faces kept open to provide an internal space 21a so that the vibration detection element 1 can be inserted therein.

The gel casing 21 is, as illustrated in FIG. 7, rectangular in planar view. As illustrated in FIGS. 7 and 8, the internal space 21a in the gel casing 21 is rectangular in planar view from the end of one longitudinal side to the end of the other. Also, the gel casing 21 has an acoustic matching agent discharge port 21c on the end of the second longitudinal side that facilitates communication from the internal space 21a to the outside. A vibration detection element insertion portion 21b is formed at the edge of the one longitudinal side of the internal space 21a. This vibration detection element insertion portion has a smaller length in the thickness direction (i.e., the length of the vibration sensor's front side and rear side directions) than the other parts.

The internal surfaces of the gel casing 21 defining the internal space 21a may be smooth. Also, the internal surfaces of the gel casing 21 defining the internal space 21a on the outer and/or inner sides may be of wavy, with serpentine curves projecting in one direction. When the internal surface(s) is/are wavy with such serpentine curves projecting in one direction, the vibration sensor can obtain enhanced bendability on axes in the direction of the ridge lines of the curved faces, and it can more easily enhance the adherence to the surface of the living body.

An exemplary process of fabricating the gel casing 21 may be as follows: A metal die with a cavity corresponding in shape to the gel casing 21 is filled with a composite material for the gel casing while a plate body to form the internal space 21a is inserted into the composite material; after the composite material is cured, the plate body is removed.

### Acoustic Matching Agent Filling Step

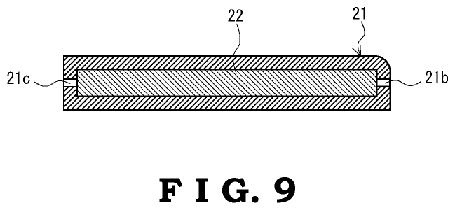

In the acoustic matching agent filling step, as illustrated in FIG. 9, the gel casing 21 prepared in the gel casing preparation step has its internal space 21a filled with the acoustic matching agent 22. The acoustic matching agent 22 may be a gel that can suppress the reflection of acoustic waves, for instance.

### Vibration Detection Element Insertion Step

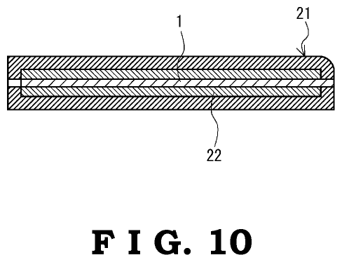

In the vibration detection element insertion step, the vibration detection element 1 is inserted into the internal space 21a of the gel casing 21, into which the acoustic matching agent 22 has been filled in the acoustic matching agent filling step. In the vibration detection element insertion step, while the vibration detection element 1 is being inserted into the internal space 21a of the gel casing 21, the acoustic matching agent 22 is discharged from the acoustic matching agent discharge port 21c by an amount equivalent to a volume of the inserted part of the vibration detection element 1. In this way, as illustrated in FIG. 10, the vibration detection element 1, with the acoustic matching agent 22 filled around the same, is held in the internal space 21a of the gel casing 21.

The method for manufacturing the vibration sensor may further include, following the vibration detection element insertion step, a step of sealing with a gel the vibration detection element insertion portion 21b and the acoustic matching agent discharge port 21c of the gel casing 21.

In the method for manufacturing the vibration sensor, the gel casing 21 comprises the rear surface side gel layer 2b and the front surface side gel layer 13b of the vibration sensor. The vibration sensor manufacturing method permits easier and more reliable fabrication of the vibration sensor.

The vibration sensor manufacturing method, including the acoustic matching agent filling step, can fill any gap that forms around the vibration detection element 1 in the internal space 21a of the gel casing 21 with the acoustic matching agent 22, and thus, the vibration detection element 1 can be held stably in the internal space 21a of the gel casing 21.

Furthermore, according to the method for manufacturing the vibration sensor, if the gel casing 21 or the vibration detection element 1 is damaged, it is easy to replace only the damaged member. Thus, the method for manufacturing the vibration sensor permits the fabrication of a vibration sensor that has superb maintainability.

### Fifth Embodiment

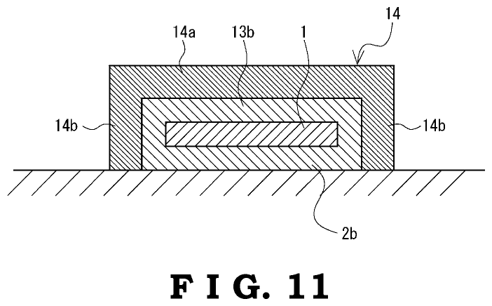

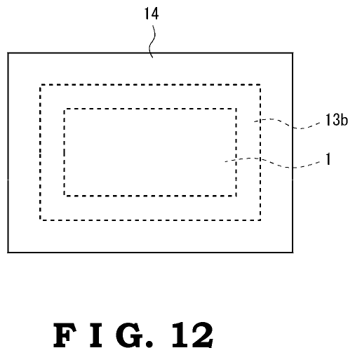

FIGS. 11 and 12 illustrate the vibration sensor in yet another embodiment of the present invention. The vibration sensor of FIGS. 11 and 12, similar to the vibration sensor in FIG. 1, is arranged to be in close contact with the surface of a living body such as a human being or an animal, and is used to detect vibrations in the living body.

The vibration sensor includes a sheet-shaped vibration detection element 1, a rear surface side gel layer 2b superposed on the side where the vibration detection element 1 faces the surface of a living body, and a front surface side gel layer 13b superposed on the side of the vibration detection element 1, which is opposite the surface of the living body. Also, the vibration sensor includes a cap 14 including a covering portion 14a and a connection portion 14b. The covering portion 14a covers a front surface side of the front surface side gel layer 13b, and is capable of pressing the front surface side gel layer 13b from the front surface side. The connection portion 14b connects the covering portion 14a to the surface of the living body.

The configuration of the vibration detection element 1 of the vibration sensor can be the same as that of the vibration detection element 1 of the vibration sensor in FIG. 1. Also, the configurations of the rear surface side gel layer 2b and the front surface side gel layer 13b of the vibration sensor can be the same as those of the rear surface side gel layer 2b and the front surface side gel layer 13b of the vibration sensor in FIG. 5. Thus, the vibration detection element 1, the rear surface side gel layer 2b, and the front surface side gel layer 13b of the vibration sensor are denoted by the same reference symbols as those for the vibration sensor in FIGS. 1 and 5, and the explanations of the same have been omitted.

### Cap

The cap 14 covers the entire outer surfaces of the rear surface side gel layer 2b and the front surface side gel layer 13b except the surface of the rear surface side gel layer 2b that comes in contact with the surface of the living body. The cap 14 is configured so that it can exert pressure on the entirety of the surfaces of the rear surface side gel layer 2b and the front surface side gel layer 13b except the surface of the rear surface side gel layer 2b that comes in contact with the surface of the living body. In this embodiment, the cap 14 directly covers the outer surfaces of the rear surface side gel layer 2b and the front surface side gel layer 13b.

The cap 14 has the shape of a bottomed square tube that is flat as a whole, and the bottom of the bottomed square tube serves as the covering portion 14a while the square tube portion serves as the connection portion 14b. The open end of the connection portion 14b is made flush with the rear surface of the rear surface side gel layer 2b, and in this way, the edge at the open end of the connection portion 14b is able to come in contact with the surface of the living body.

The cap 14, having its connection portion 14b kept in contact with the surface of the living body, prevents the vibration detection element 1 from detecting any movement of the living body other than the vibrations in the living body. The covering portion 14a pushes the front surface side of the front surface side gel layer 13b upon transmission of the biological vibrations from the surface of the living body to the front surface side gel layer 13b, highly facilitating the vibration detection element 1's detection of vibrations. Specifically, the cap 14 selectively increases the detection sensitivity based on the compression deformation of the piezoelectric member 3 resulting from biological vibrations, and suppresses the detection of any deformation other than such compression deformation.

Examples of the material for the cap 14 include a rigid material such as a metal. Thus, the cap 14, being made of a rigid material, can readily function as an outer wall of the rear surface side gel layer 2b and the front surface side gel layer 13b, selectively increases the detection sensitivity based on the compression deformation of the piezoelectric member 3 resulting from biological vibrations, and easily suppresses the detection of deformations other than the compression deformation. For the material of the cap 14, a thermoplastic resin such as polyethylene terephthalate may be used.

The vibration sensor, having the cap 14 that is comprised of the covering portion 14a, which is capable of pushing the front surface side to press the front surface side gel layer 13b down, and the connection portion 14b, which connects the covering portion 14a to the surface of the living body, facilitates the selective, easy, and reliable detection of biological vibrations.

### Embodiment for Reference

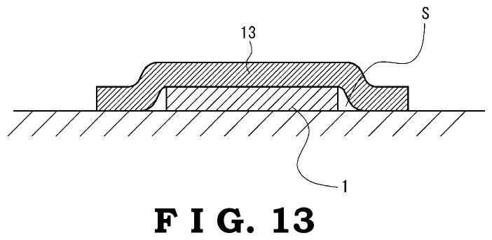

FIG. 13 illustrates a vibration sensor in an embodiment for reference related to the present invention. The vibration sensor in FIG. 13 is, similar to the vibration sensor in FIG. 1, disposed in close contact with the surface of a living body such as a human being or an animal, and is used to detect the vibrations in the living body.

The vibration sensor includes a sheet-shaped vibration detection element 1 and a front surface side gel layer 13 superposed on the side where the vibration detection element 1 faces the surface of the living body. The front surface side gel layer 13 extends beyond the vibration detection element 1 in planar view. Also, spaces S are formed between the end faces of the vibration detection element 1 and the front surface side gel layer 13.

The configuration of the vibration detection element 1 of the vibration sensor can be the same as that of the vibration detection element 1 of the vibration sensor in FIG. 1. Also, the configuration of the front surface side gel layer 13 of the vibration sensor can be the same as that of the front surface side gel layer 13 of the vibration sensor in FIG. 3.

The vibration sensor, having the front surface side gel layer 13 superposed on the front surface side of the vibration detection element 1, facilitates the detection of the biological vibrations.

### Other Embodiments

The aforementioned embodiments are not intended to limit the present invention to particular forms. Thus, those embodiments can have their respective components omitted, replaced, or otherwise complemented in light of the description of this specification and technological common knowledge, and they should all be interpreted as within the scope of the present invention.

In the vibration sensor, the shield layer, the isolator layer, and the protective layer are optional components and may be omitted individually. Also, in the vibration sensor, the shield layer and the protective layer may be formed separately, and those on either or both of the front side and the rear side surfaces may be omitted individually.

In the vibration sensor, the shield layer on the front surface side and the shield layer on the rear surface side may be of a single-sheet structure, folded in two. When one of the electrodes is connected to ground, the grounding electrode can function as an electromagnetic shield even if the shield layer covering the grounding electrode is omitted.

In the vibration sensor, one of the electrodes may be grounded by means of the human body by using a conductive gel as the material for the gel layer and electrically connecting the resultant conductive gel layer to one of the electrodes, preferably the one on the rear surface side. In this way, wiring for grounding is not required, which make it easy to measure vibrations.

An example of the method of making the gel layer conductive as in the above includes a method in which a gel dispersion medium used for forming the gel layer includes, for instance, a metal ion or a complex (for organogel, a polar solvent is used as the dispersion medium).

Moreover, it is also possible, as a process of connecting the electrode on the rear surface side to the gel layer, to adopt a process of making an opening or a notch in a film comprised at least of the shield layer and usually of the shield layer and the protective layer integrated with each other, thereby electrically connecting the electrode to the gel layer directly or through the shield layer.

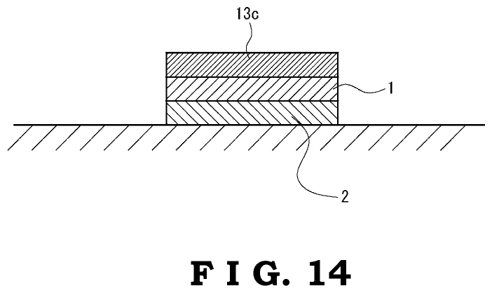

The configurations of the aforementioned embodiments can be used in any appropriate combination. For example, each of the vibration sensors in FIGS. 1 to 3 and FIG. 13 may include the cap. Also, the rear surface side gel layer 2 of the vibration sensor in FIG. 3 may be replaced with the rear surface side gel layer 2a along with the frame member 12 of the vibration sensor in FIG. 2. Additionally, as illustrated in FIG. 14, when the vibration sensor has a rear surface side gel layer 2 and a front surface side gel layer 13c shaped in separate sheet members, it is unnecessary for the front surface side gel layer 13c to extend beyond the vibration detection element 1 in planar view. Not having the front surface side gel layer 13c extend beyond the vibration detection element 1 in planar view makes it easier to detect not only biological vibrations, but a variety of movements of the living body. Furthermore, in the vibration sensor in FIG. 13, the front surface side gel layer 13 may be arranged so that it does not extend beyond the vibration detection element 1 in planar view.

In the vibration sensor, in the case where the front surface side gel layer extends beyond the vibration detection element in planar view, the front surface side gel layer may extend out from only a part of the peripheral edge of the vibration detection element. In the case where the front surface side gel layer extends out from only a part of the peripheral edge of the vibration detection element, it is preferable that the front surface side gel layer extend out from the edges of a pair of opposing sides of the vibration detection element. By arranging the vibration sensor such that overhanging regions of the front surface side gel layer that extend beyond the edges of a pair of opposing sides of the vibration detection element adhere to the surface of the living body, it is easier to suppress the deformation of the piezoelectric member in response to movements of the living body other than the biological vibrations.

When the rear surface side gel layer and the front surface side gel layer are shaped integrally, it is not required that these gel layers be connected outside the vibration detection element. In the vibration sensor, for example, the vibration detection element has one or more through-holes arranged perpendicularly, and the rear surface side gel layer and the front surface side gel layer may be integrated with each other by filling the gel layer into the through-hole(s). This configuration can also prevent the rear surface side gel layer and/or the front surface side gel layer from being peeled off from the vibration detection element.

In the case where the vibration sensor has the above-mentioned cap, it is not necessary for the cap to have a bottomed tube shape. The cap may have a configuration that includes, for example, a rectangular covering portion covering the front surface side of the front surface side gel layer, and a pair of connection portions extending out from the edge on a pair of opposing sides of the covering portion toward the surface of the living body.

Protrusions and recesses may be formed on the front surface or the rear surface of the front surface side gel layer. For example, a plurality of slits extending in the same direction may be provided in parallel at predetermined intervals in the front surface or the rear surface of the front surface side gel layer. With such a configuration, the bending direction of the vibration sensor can be controlled by these slits. Specifically, this configuration could facilitate the stable retainment of the vibration sensor's bent shape, as the bending will occur on an axis along the direction of the slits. This results in the vibration sensor more advantageously enhancing its adherence to the surface of the living body.

The vibration sensor may also have an arrangement where two or more vibration detection elements are covered by the rear surface side gel layer and the front surface side gel layer. Such a configuration can more easily secure uniformity of the detection sensitivity of the vibration detection elements.

The vibration sensor may replace the above-mentioned isolator layer 8 with a gel layer.

A method comprising a gel casing preparation step, an acoustic matching agent filling step, and a vibration detection element insertion step has been described as the method for manufacturing the vibration sensor in the fourth embodiment; however, the method for manufacturing the vibration sensor, so far as it guarantees the secure retainment of the vibration detection element in the gel casing's internal space, is not necessarily required to include the acoustic matching agent filling step.

The vibration sensor according to the present invention can be utilized to measure a variety of vibrations originating in the body of a human being or an animal.

### EXPLANATION OF THE REFERENCE SYMBOLS

1 Vibration detection element
2, 2a, 2b Rear surface side gel layer
3 Piezoelectric member
4, 5 Electrodes
6, 7 Shield layer
8 Isolator layer
9, 10 Protective layer
11 Lead
12 Frame member
13, 13b, 13c Front surface side gel layer
14 Cap
14a Covering portion
14b Connection portion
21 Gel casing
21a Internal space
21b Vibration detection element insertion portion
21c Acoustic matching agent discharge port
22 Acoustic matching agent
P Overhanging region
S Space

1. A vibration sensor configured to be adhered to a surface of a living body and to detect biological vibrations originating in the living body, the vibration sensor comprising:
a vibration detector having a first side that faces the surface of the living body in a state where the vibration sensor is adhered to the surface of the living body and a second side opposite across a thickness of the vibration detector from the first side, the vibration detector including a sheet-shaped piezoelectric member, a first electrode disposed on a first side of the piezoelectric member, and a second electrode disposed on a second side of the piezoelectric member opposite across a thickness of the piezoelectric member from the first side of the piezoelectric member; and
a first gel layer that covers the second side of the vibration detector,
wherein the first gel layer extends beyond the vibration detector in planar view such that at least a part of the first gel layer is configured to be adhered to the surface of the living body in the state where the vibration sensor is adhered to the surface of the living body.

2. The vibration sensor according to claim 1, wherein the first gel layer extends beyond the vibration detector in planar view such that spaces are respectively provided between the first gel layer and end faces of the vibration detector.

3. The vibration sensor according to claim 1, further comprising a second gel layer that covers the first side of the vibration detector and is configured to adhere the vibration sensor to the surface of the living body.

4. The vibration sensor according to claim 1, wherein the vibration detector further includes an electrically non-conductive isolator layer disposed on the first electrode such that the electrically non-conductive isolator layer is disposed between the first electrode and the first gel layer.

5. The vibration sensor according to claim 2, wherein the vibration detector further includes an electrically non-conductive isolator layer disposed on the first electrode such that the electrically non-conductive isolator layer is disposed between the first electrode and the first gel layer.

6. The vibration sensor according to claim 3, wherein the vibration detector further includes an electrically non-conductive isolator layer disposed on the first electrode such that the electrically non-conductive isolator layer is disposed between the first electrode and the first layer.

7. The vibration sensor according to claim 4, wherein the electrically non-conductive isolator layer and the piezoelectric member are made of the same material as each other.

8. The vibration sensor according to claim 4, wherein an average thickness of the electrically non-conductive isolator layer and an average thickness of the piezoelectric member are the same as each other.

9. The vibration sensor according to claim 7, wherein an average thickness of the electrically non-conductive isolator layer and an average thickness of the piezoelectric member are the same as each other.
